(19) United States
(12) Patent Application Publication
(10) Pub. No.: US 2014/0252296 A1
(43) Pub. Date: Sep. 11, 2014

(54) RESISTIVE RANDOM-ACCESS MEMORY

(71) Applicant: National Tsing Hua University, Hsinchu (TW)

(72) Inventors: Yu-Lun CHUEH, Hsinchu (TW); Chung-Nan PENG, Hsinchu (TW); Wen-Chun YEN, Hsinchu (TW)

(73) Assignee: National Tsing Hua University, Hsinchu (TW)

(21) Appl. No.: 14/197,697

(22) Filed: Mar. 5, 2014

(30) Foreign Application Priority Data
Mar. 5, 2013 (TW) 102107592

(51) Int. Cl. H01L 45/00

(52) U.S. Cl. CPC H01L 45/146
USPC 257/3

(57) ABSTRACT

The present invention relates to a resistive random-access memory, including: a bottom electrode; a resistive switch layer disposed on the bottom electrode, including a first switch layer, a second switch layer, and a filament path control layer, wherein the first switch layer is interposed between the bottom electrode and the filament path control layer, and the filament path control layer is interposed between the first switch layer and the second switch layer; and a top electrode disposed on the second switch layer, wherein the filament path control layer includes one or more micro-pores. The present invention also relates to a memory array which includes a substrate and a plurality of the above-mentioned resistive random access memories, wherein the resistive random access memories are disposed on the substrate.

### CROSS REFERENCE TO RELATED APPLICATION

This application claims the benefits of the Taiwan Patent Application Serial Number 102107592, filed on Mar. 5, 2013, the subject matter of which is incorporated herein by reference.

### BACKGROUND OF THE INVENTION

1. Field of the Invention

The present invention relates to a resistive random-access memory, and more particularly, to a resistive random-access memory in which a filament path control layer is used to control a filament path.

2. Description of Related Art

With rapid development and demand of mobile communication devices, non-volatile memory has become an essential part of the devices by virtue of its low energy consumption, and the ability to maintain stored information without power supply. Among various non-volatile memories, resistive random access memory (RRAM) is the most extensively developed one in recent years because of simple structure, and easy integration with other electronic devices.

A resistive random access memory structure generally includes a top electrode, a bottom electrode, and a resistive switch layer interposed therebetween. Through applying an operating voltage across the top electrode and the bottom electrode at the opposite sides of the resistive switch layer, a filament path may be formed in the resistive switch layer, or a previously formed filament path may be broken depending on the applied operating voltage. The filament path serves as a current path, so that the resistive random access memory has a low resistance set mode and a high resistance reset mode to achieve the purpose of data access. At present, most researches on the resistive random access memory focus on the materials of the resistive switch layers. However, because of the mechanism of forming the filament path in the resistance layer, after several operations, the formed filament path become very coarse or difficult to control the generation position, thereby causing stability problems in the resistive random access memory.

Therefore, there is a demand for developing a resistive random access memory, in which the position and size of the filament path can be precisely controlled so as to improve or maintain the stability of the resistive random access memory during operation.

### SUMMARY OF THE INVENTION

An object of the present invention is to provide a resistive random access memory, in which the position and size of the filament path in a resistive switch layer can be precisely controlled so as to maintain the current-voltage stability of the resistive random access memory during operation.

To achieve the above object, the present invention provides a resistive random-access memory, comprising: a bottom electrode; a resistive switch layer disposed on the bottom electrode, comprising a first switch layer, a second switch layer, and a filament path control layer, wherein the first switch layer is interposed between the bottom electrode and the filament path control layer, and the filament path control layer is interposed between the first switch layer and the second switch layer; and a top electrode disposed on the second switch layer, wherein one or more micro-pores locates in or on the filament path control layer. When an operating voltage is applied across the top electrode and the bottom electrode, a filament path may be formed in the resistive switch layer, and a filament path control layer may precisely control the generation position and size of the filament path through one or more micro-pores included therein, so as to maintain the current-voltage stability of the resistive random access memory during the operating process.

In the resistive random-access memory of the present invention, the material of the filament path control layer is not particularly limited, as long as it may precisely control the generation position and size of the filament path formed in the resistive switch layer. For example, in an aspect of the present invention, the filament path control layer may be composed of single or multiple graphene layers, thereby precisely controlling the generation position and size of the filament path formed in the resistive switch layer. In addition, the thickness of the filament path control layer is also not particularly limited, as long as it may precisely control the generation position and size of the filament path formed in the resistive switch layer. For example, in an aspect of the present invention, the filament path control layer may have a thickness of 1 nm to 10 nm. Preferably, in an embodiment of the present invention, the filament path control layer may have a thickness of 5 nm to 10 nm. Furthermore, the pore size of the micro-pores is also not particularly limited, as long as it may precisely control the generation position and size of the filament path formed in the resistive switch layer. For example, in an aspect of the present invention, the micro-pores may have a pore size of 0.1 μm to 10 μm. Preferably, in an embodiment of the present invention, the micro-pores may have a pore size of 1 μm to 10 μm.

In the resistive random-access memory of the present invention, any conventional materials suitable for forming the resistive switch layer of the resistive random-access memory may be used as the materials of the first switch layer and the second switch layer, including but not particularly limited to, for example, dielectric materials, ferroelectric materials, ferromagnetic materials, or semiconductor materials. More preferably, exemplary materials for the resistive switch layer of the resistive random-access memory comprise: (1) binary transition metal oxides, such as TiOx, VOx, CrOx, MnOx, FeOx, CoOx, NiO, and CuOx; (2) perovskite-type complex transition metal oxides, such as strontium titanate (SrTiO3), strontium zirconate (SrZrO3), lead titanate (PbTiO3), and praseodymium calcium manganite (PCMO); (3) high dielectric constant oxides, such as Al2O3, anodic aluminium oxide (AAO), HfO2, Gd2O3; (4) chalcogenides, such as GaV4S8; (5) semiconductor material, such as SiO2; (6) carbon-based materials, such as grahene oxide, but the present invention is not limited thereto. In an aspect of the present invention, the first switch layer and the second switch layer may be independently silicon dioxide (SiO2), titanium dioxide (TiO2), vanadium dioxide (VO2), chromium(III) oxide (Cr2O3), manganese oxide, iron oxide, cobalt oxide, nickel oxide (NiO), copper oxide, strontium titanate (SrTiO3), strontium zirconate (SrZrO3), lead titanate (PbTiO3), praseodymium calcium manganite (PCMO), aluminum oxide (AlOx), hafnium oxide (HfOx), gadolinium sesquioxide (Gd2O3), or a combination thereof. In addition, in the resistive random-access memory of the present invention, the first switch layer and the second switch layer may be made of the same or different materials. For example, in an embodiment of the present invention, the first switch layer and the second switch layer may be both silicon dioxide.

Further, the thicknesses of the first switch layer and the second switch layer are also not particularly limited, as long as they can maintain the signal stability of the resistive random-access memory of the present invention during the operating process. For example, in an aspect of the present invention, the first switch layer may have a thickness of 25 μm to 100 μm while the second switch layer may have a thickness of 25 μm to 100 μm. Preferably, in an embodiment of the present invention, the first switch layer may have a thickness of 50 μm to 100 μm while the second switch layer may have a thickness of 50 μm to 100 μm. In other words, according to the present invention, the position of the filament path control layer in the resistive switch layer can be adjusted by regulating the thicknesses of the first switch layer and the second switch layer, so as to optimize the current-voltage stability of the produced resistive random access memory.

In the resistive random-access memory of the present invention, the materials of the bottom electrode and the top electrode are not particularly limited, and any conventional material suitable for forming the electrode of the resistive random-access memory may be used. For example, in an aspect of the present invention, the bottom electrode and the top electrode may be independently made of Pt, Ti, Au, Cu, Al, Ru, Ag, Ta, nitrides thereof, or alloys thereof. Preferably, in an embodiment of the present invention, the bottom electrode and the top electrode may be independently made of Pt or Ag.

Also, the shapes of the bottom electrode and the top electrode are not particularly limited, and any shape may be used, for example: rectangle, square, circle, etc. For example, in an aspect of the present invention, the bottom electrode may be square while the top electrode may be circle. Similarly, the size of the bottom electrode and the top electrode is not particularly limited. For example, in an aspect of the present invention, the contact area between the bottom electrode and the first switch layer may be larger than the contact area between the top electrode and the second switch layer; in another aspect of the present invention, the contact area between the bottom electrode and the first switch layer is equal to the contact area between the top electrode and the second switch layer, but the present invention is not limited thereto.

Accordingly, comparing to the conventional resistive random-access memory, the present invention uses the filament path control layer disposed in the resistive switch layer to confine the position and size of the filament path formed in the resistive switch layer, and as a result, the resistive random-access memory of the present invention may provide a better current-voltage stability, and the difference between the high and low resistance may be maintained after several operation cycles.

Another object of the present invention is to provide a memory array, so as to maintain the current-voltage stability of the produced memory array in the operating process through the technical features of the above-mentioned resistive random access memory of the present invention.

To achieve the above object, the present invention provides a memory array, including a substrate and a plurality of the resistive random access memories as described above, wherein the resistive random access memories are disposed on the substrate and may be composed of a plurality of bottom electrodes, a plurality of top electrodes and a plurality of resistive switch layers interposed therebetween, to form a memory array with a crossing switch structure.

More specifically, in the memory array of the present invention, the resistive switch layers include a first switch layer, a second switch layer, and a filament path control layer, wherein the first switch layer is interposed between the bottom electrode and the filament path control layer, and the filament path control layer is interposed between the first switch layer and the second switch layer, wherein the filament path control layer includes one or more micro-pores. Thus, when an operating voltage is applied across the top electrode and the bottom electrode, a filament path may be formed in the resistive switch layer, and a filament path control layer may precisely control the generation position and size of the filament path through one or more micro-pores included therein, so as to maintain the current-voltage stability of the resistive random access memory in the operating process.

In the memory array of the present invention, the substrate may be made of various materials, and not particularly limited. For example, in an aspect of the present invention, the substrate may be a plastic substrate, a metal substrate, a ceramic substrate, or a combination thereof, and preferably a plastic substrate, an aluminum substrate, a glass substrate, or a silicon substrate, but the present invention is not limited thereto. In an embodiment of the present invention, the substrate may be a plastic substrate, and thus the produced memory array may be a flexible memory array.

Accordingly, the memory array prepared using the technology of the resistive random-access memory of the present invention may provide a better current-voltage stability, and the difference between the high and low resistance may be maintained after several operation cycles.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A-1G are the flow chart showing the manufacturing process of the resistive random-access memory according to Example 1 of the present invention.

FIGS. 2A-2D are the microscopic images of the resistive random-access memory according to Example 1 of the present invention.

FIG. 3 shows the Raman spectrums of the resistive random-access memory according to Example 1 of the present invention.

FIG. 4A shows the current versus voltage curve of the resistive random-access memory according to Example 1 of the present invention.

FIG. 4B shows the curve of high-low resistance distribution of the resistive random-access memory according to Example 1 of the present invention.

FIG. 5 shows the schematic diagram of the structure of the memory array according to Example 2 of the present invention.

FIG. 6A shows the current versus voltage curve of the memory array before being flexed according to Example 2 of the present invention.

FIG. 6B shows the curve of high-low resistance distribution of the memory array before being flexed according to Example 2 of the present invention.

FIG. 7A shows the current versus voltage curve of the memory array after being flexed according to Example 2 of the present invention.

FIG. 7B shows the curve of high-low resistance distribution of the memory array after being flexed according to Example 2 of the present invention.

FIG. 8A shows the current versus voltage curve of the resistive random-access memory according to Comparative Example 1.

FIG. 8B shows the curve of high-low resistance distribution of the resistive random-access memory according to Comparative Example 1.

FIG. 9A shows the current versus voltage curve of the resistive random-access memory according to Comparative Example 2.

FIG. 9B shows the curve of high-low resistance distribution of the resistive random-access memory according to Comparative Example 2.

### DETAILED DESCRIPTION OF THE PREFERRED EMBODIMENT

[symbol] Preparation of Graphene

[symbol]

### Preparation Example

First, a copper foil was prepared and washed sequentially by acetone and deionized water to remove the oil contamination and dust on the surface of the copper foil. Then, under the protection of a gas with an argon/hydrogen flow rate ratio of 200/10 sccm, the copper foil was subjected to annealing for 30 minutes twice. Methane was introduced with a flow rate of 20 sccm for reaction for 30 minutes at a temperature of 1000° C. and a pressure of 0.6 Ton to form a graphene layer on the surface of the copper foil. Subsequently, the temperature was lowered to 180° C. and maintained for 1 minute. Finally, oxygen was introduced with a flow rate of 100 sccm to form micro-pores in the graphene layer.

[symbol] Preparation of Resistive Random-Access Memory

[symbol]

### Example 1

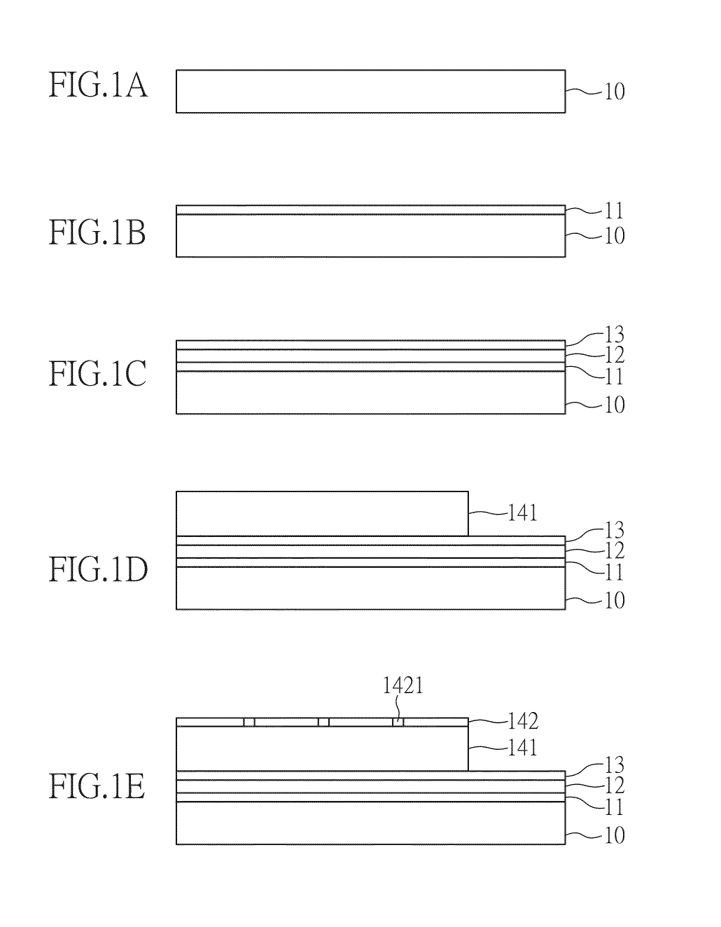

FIGS. 1A-1C show the manufacturing process of the resistive random-access memory of the present example of the present invention. First, referring to FIG. 1A, a substrate 10 composed of silicon was provided. Then, as show in FIG. 1B, silicon dioxide with a thickness of 1 μm was formed on the surface of the substrate 10 to serve as an insulator 11.

Referring to FIG. 1C, an adhesive layer 12 and a bottom electrode 13 were formed on the insulator 11, wherein the adhesive layer 12 functions to enhance the adhesion between the bottom electrode 13 and the insulator 11. In the present example, the adhesive layer 12 and the bottom electrode 13 were formed on the insulator 11 independently by radio frequency sputtering. In the present example, the adhesive layer 12 was titanium with a thickness of 40 nm, while the bottom electrode 13 was platinum. Referring to FIG. 1D, a first switch layer 141 was formed on the bottom electrode 13 by electron beam evaporation. In the present example, the first switch layer 141 was silicon dioxide with a thickness of 50 μm.

Then, referring to FIG. 1E, a filament path control layer 142 was formed on the first switch layer 141, and there are one or more micro-pores 1421 in the filament path control layer 142. In the present example, the filament path control layer 142 was the graphene layer prepared in the Preparation Example, and the graphene layer was transferred onto the first switch layer 141 from the surface of the copper foil by a poly(methyl methacrylate) (PMMA) film. Next, as shown in FIG. 1F, a second switch layer 143 was formed on the filament path control layer 142 by electron beam evaporation. In the present example, the second switch layer 143 was silicon dioxide with a thickness of 50 μm. Finally, as shown in FIG. 1G, a top electrode 15 was formed on the second switch layer 143 by electron beam evaporation, wherein the top electrode 15 was silver. In the present example, the contact area between the top electrode 15 and the second switch layer 143 was less than the contact area between the bottom electrode 13 and the first switch layer 141.

Accordingly, as shown in FIGS. 1A-1G, the resistive random-access memory 1 of the present example was formed on the substrate 10. The resistive random-access memory 1 of the present example includes a bottom electrode 13, a resistive switch layer 14 disposed on the bottom electrode 13, and a filament path control layer 142. Moreover, the resistive switch layer 14 includes a first switch layer 141, and a second switch layer 143. In the present example, the first switch layer 141 was interposed between the bottom electrode 13 and the filament path control layer 142, and the filament path control layer 142 was interposed between the first switch layer 141 and the second switch layer 143. In addition, a top electrode 15 disposed on the second switch layer 143, and there are one or more micro-pores 1421 in the filament path control layer 142. In the present example, the bottom electrode 13 was platinum, and the top electrode 15 was silver, while the first switch layer 141 and the second switch layer 143 were silicon dioxide, and the filament path control layer 142 was the graphene layer.

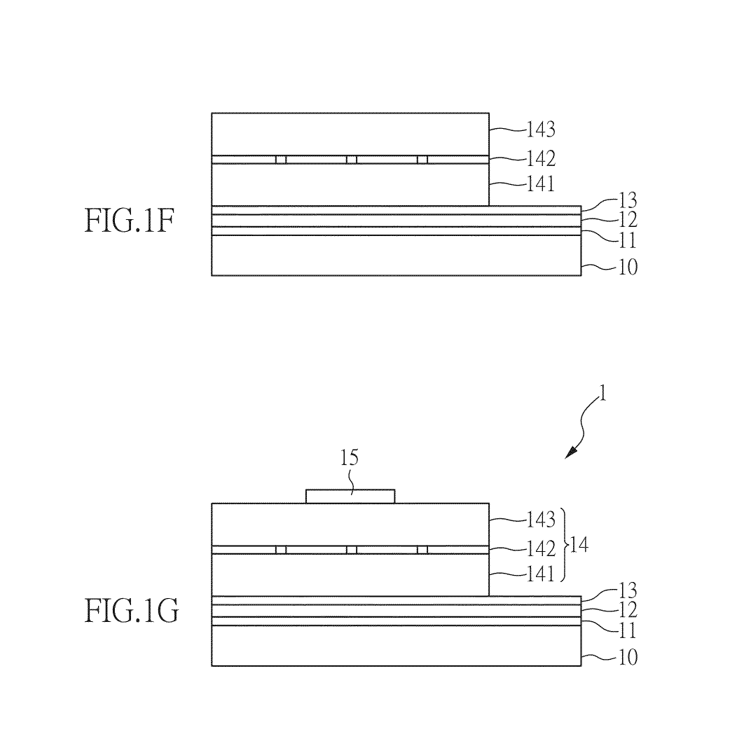

Moreover, please continue to refer to FIGS. 2A-2D, which show the microscopic images of the resistive random-access memory of the present example of the present invention. Referring to FIG. 2A, it was confirmed that the filament path control layer 142 was formed between the first switch layer 141 and the second switch layer 143. In addition, FIG. 2B is the enlarged view of the portion A in FIG. 2A. Referring to FIG. 2B and FIG. 2A together, it can be seen that the lattice spacing was 0.33 nm, and it is confirmed that the graphene layer functioning the filament path control layer 142 is formed. Through a calculation, the graphene layer with a thickness of 6.6 nm is consisted of 20 layers of graphene.

Then, referring to FIG. 2C, which shows the distribution of the filament path formed in the resistive switch layer 14 after the completion of the fabrication process of the resistive random-access memory of described above. In the present example, because of electrochemical metallization (ECM) mechanism, the filament path was made of silver dissociated from the top electrode 15. Since the formed filament path could pass the graphene layer only through the micro-pores, it indicates that the graphene layer functioning as the filament path control layer could indeed control the size and position of the formed filament path. Furthermore, FIG. 2D is the enlarged view of the B portion in FIG. 2C. Referring to FIG. 2D and FIG. 2C together, it can be seen that the lattice spacing was 0.27 nm, and it also indicates that the filament path was made of silver.

Subsequently, please refer to Table 1, which shows the result of elemental analysis at the positions 1 to 3 in FIGS. 2A-2D. As shown in Table 1, the position 1 only contained elements having a Si/O ratio of 1/2. This result indicates that before the fabrication process, the first switch layer only contained silicon dioxide. The position 2 contained 76% by weight of silver, and it indicates that after the fabrication process, the filament path made of silver was formed in the resistive switch layer. The position 3 is a position consisted essentially of silicon dioxide without silver. Although the position 3 was adjacent to the filament path, it barely contained any silver, indicating that the graphene layer was able to control the generation position and size of the filament path.

TABLE 1
Position Element content (atom %)

Element content (atom %)

| Position | (Ag) | (Pt) | (Si) | (O) |
|---|---|---|---|---|
| 1 | 0 | 0 | 37.3 | 62.7 |
| 2 | 76.4 | 0 | 15 | 8.6 |
| 3 | 0.1 | 0 | 29.5 | 70.5 |

Accordingly, the results of FIGS. 2A-2D and Table 1 confirmed that the size and position of the formed filament path formed in the resistive switch layer 14 can be controlled by the graphene layer functioning as a filament path control layer in the resistive random-access memory of the present example.

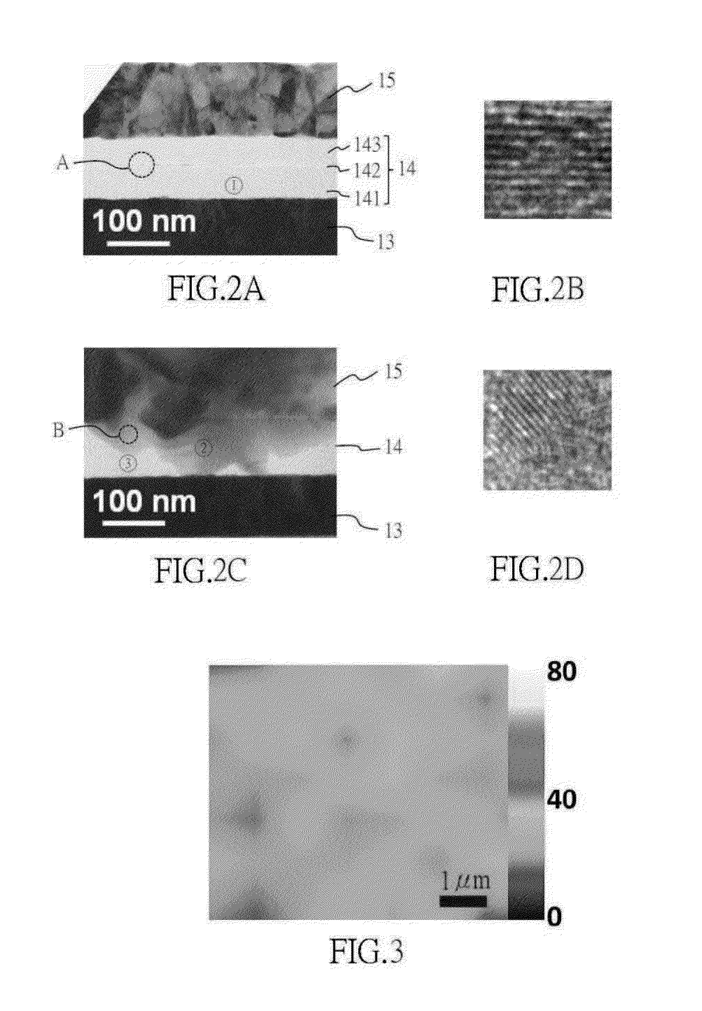

Next, refer to FIG. 3, which shows the Raman spectrums of the resistive random-access memory according to the present example of the present invention. As shown in FIG. 3, the green portion represents the distribution of the G band peak at 1570 cm⁻¹ of the graphene layer functioning as the filament path control layer 142, and thus, it can be seen from the result that the micro-pores 1421 locating in the graphene layer (functioning as the filament path control layer 142) have a pore-size of 1 μm.

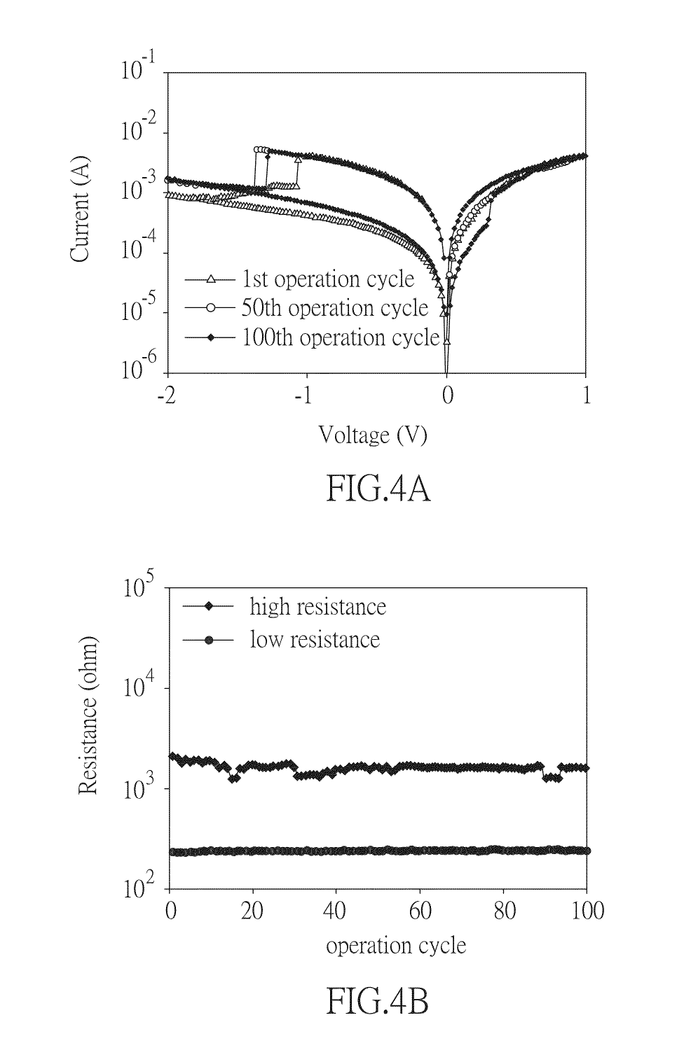

Furthermore, refer to FIG. 4A, which shows the current versus voltage curve of the resistive random-access memory 1 of the present example, and the result indicates that the resistive random-access memory 1 can maintain its current-voltage stability after 100 times of operation cycles. FIG. 4B shows the curve of high-low resistance distribution of the resistive random-access memory according to the present example of the present invention. Referring to FIG. 4B and FIG. 4A together, the result indicates that the resistive random-access memory 1 can maintain its high-low resistance stability during 100 times of operation cycles.

### Example 2

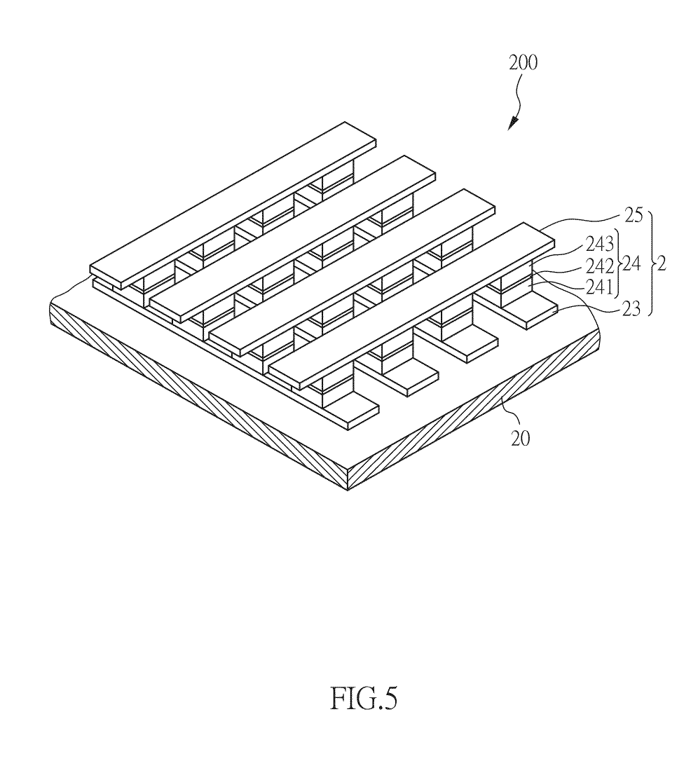

Please refer to FIG. 5, which shows the schematic diagram of the structure of the memory array 200 of Example 2. The memory array 200 having a crossbar structure which includes a substrate 20 and a plurality of resistive random access memories 2 disposed on the substrate 20. The resistive random access memories 2 were formed by interposing a plurality of resistive switch layers 24 between a plurality of bottom electrodes 23 and a plurality of top electrodes 25. The resistive switch layers 24 includes a first switch layer 241, a second switch layer 243, and a filament path control layer 242, wherein the first switch layer 241 was interposed between the bottom electrode 23 and the filament path control layer 242, and the filament path control layer 242 was interposed between the first switch layer 241 and the second switch layer 243, and the filament path control layer 242 included one or more micro-pores. In the present example, the substrate was a plastic substrate, the bottom electrode 23 was platinum, and the top electrode 25 was silver. The first switch layer 241 and the second switch layer 243 were silicon dioxide, and the filament path control layer 242 was the graphene layer prepared in the above Preparation Example. Since the substrate was a plastic substrate, the produced memory array 200 was a flexible memory array.

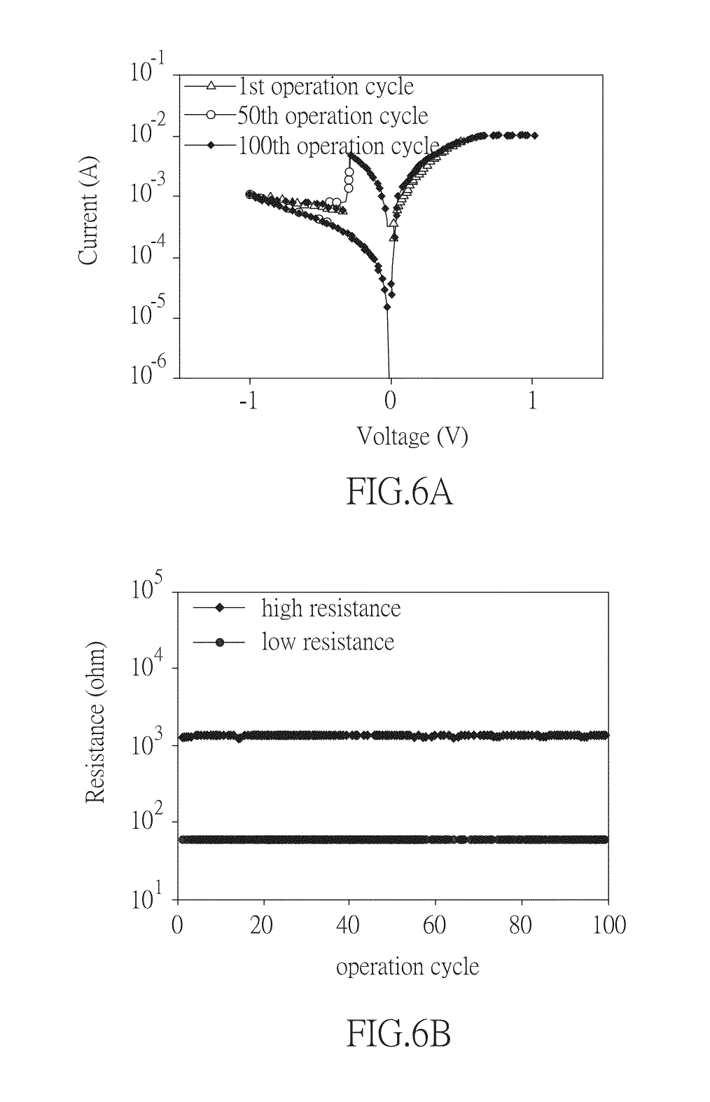

FIG. 6A shows the current versus voltage curve of the memory array 200 of the present example before being flexed. The result indicates that the memory array 200 can maintain its current-voltage stability after 100 times of operation cycles. FIG. 6B shows the curve of high-low resistance distribution of the memory array before being flexed according to the present example of the present invention. Referring to FIG. 6B and FIG. 6A together, the result indicates that the memory array 200 can maintain its high-low resistance stability after 100 times of operation cycles.

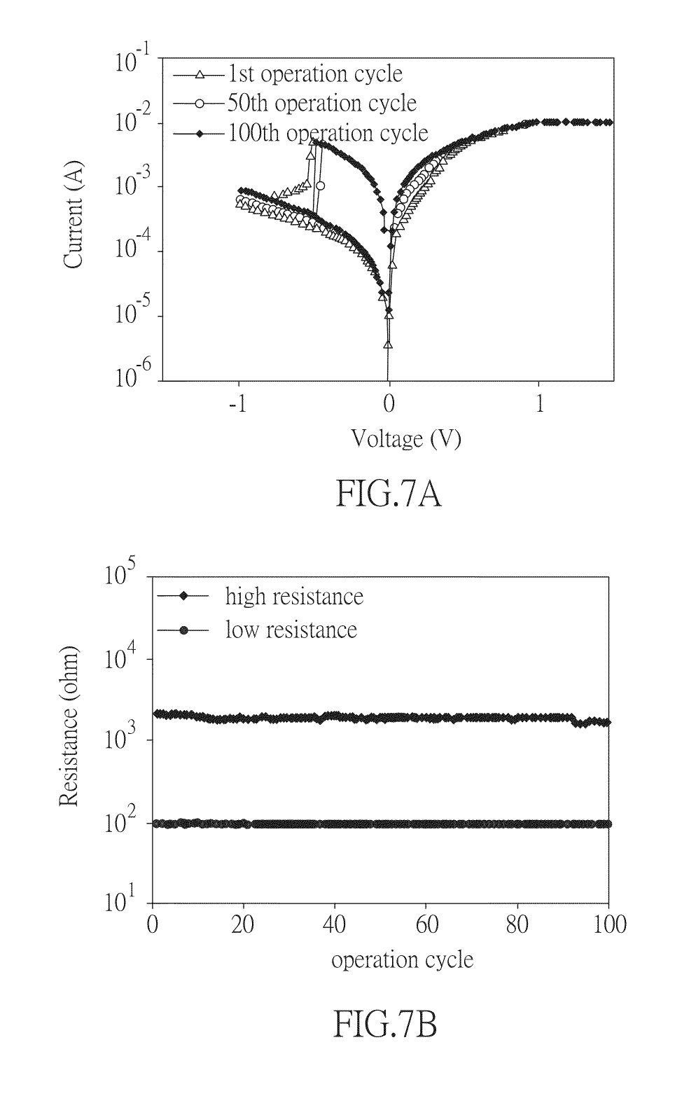

Please refer to FIG. 7A, which shows the current versus voltage curve of the memory array 200 of the present example after being flexed. The result indicates that the memory array 200 with a curvature of 1 cm⁻¹ can maintain its current-voltage stability after 100 times of operation cycles. FIG. 7B shows the curve of high-low resistance distribution of the memory array after being flexed according to the present example of the present invention. Referring to FIG. 7B and FIG. 7A together, the result indicates that the memory array 200 with a curvature of 1 cm⁻¹ can maintain its high-low resistance stability after 100 times of operation cycles.

### Comparative Example 1

The resistive random-access memory in Comparative Example 1 was substantially the same as that described in Example 1, except that the resistive switch layer only included a first switch layer and a second switch layer 243, that is, a filament path control layer was not included. Accordingly, the resistive random-access memory of Comparative Example 1 was prepared as a counterpart of Example 1 without the filament path control layer.

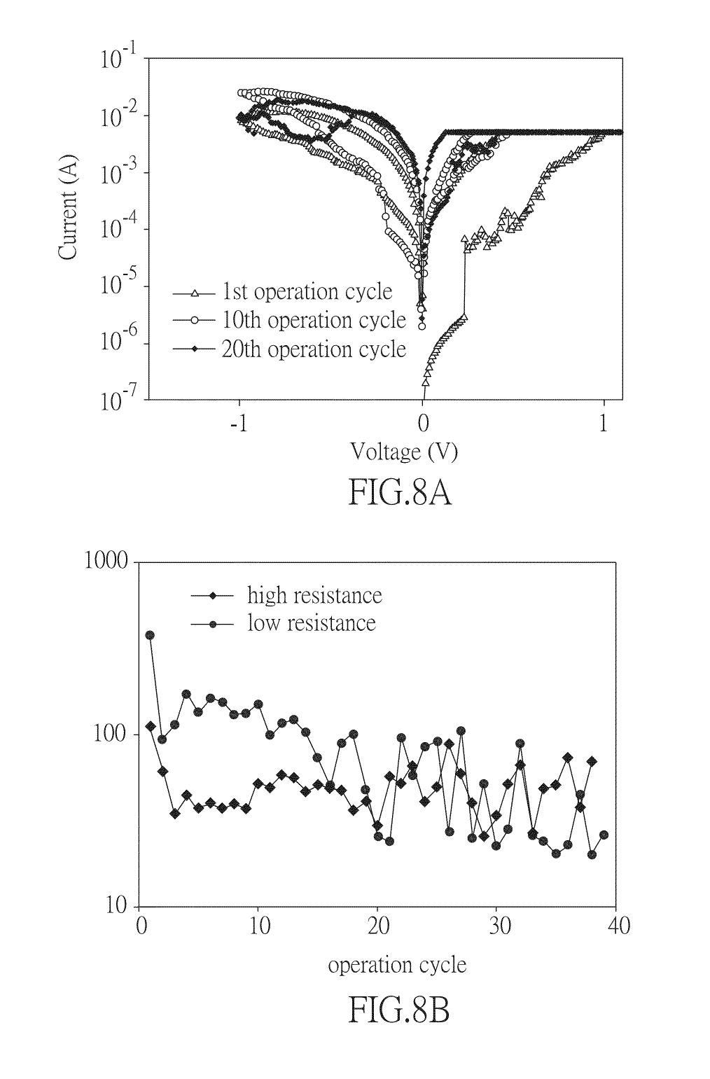

Referring to FIG. 8A, which shows the current versus voltage curve of the resistive random-access memory of Comparative Example 1 after being flexed, the result indicates that the resistive random-access memory had an unstable current-voltage state after 20 times of operation cycles. FIG. 8B shows the curve of high-low resistance distribution of the resistive random-access memory according to Comparative Example 1. Referring to FIG. 8B and FIG. 8A together, the result indicates that the resistive random-access memory has an unstable high-low resistance state after 15 times of operation cycles, and the high-low resistance state became undistinguishable.

### Comparative Example 2

The resistive random-access memory in Comparative Example 2 was substantially the same as that described in Example 1, except that the resistive switch layer was silicon dioxide with a thickness of 100 nm, and a filament path control layer was not included. Accordingly, the resistive random-access memory without a filament path control layer was prepared in Comparative Example 2.

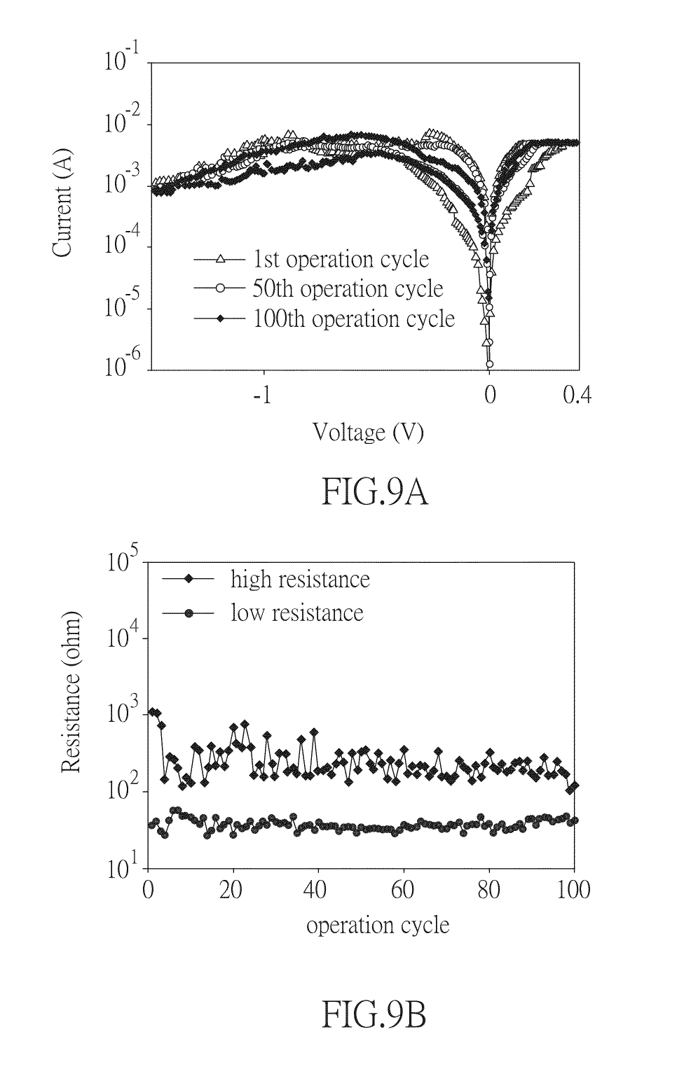

Referring to FIG. 9A, which shows the current versus voltage curve of the resistive random-access memory of Comparative Example 2 after being flexed. Comparing to the resistive random-access memory of Comparative Example 1, the resistive random-access memory of Comparative Example 2 exhibited a relatively stable current-voltage state after 100 times of operation cycles. FIG. 9B shows the curve of high-low resistance distribution of the resistive random-access memory according to Comparative Example 2. However, referring to FIG. 9B and FIG. 9A together, the result indicates that the resistive random-access memory trended to have an unstable high-low resistance state after 100 times of operation cycles. In addition, comparing to high-low resistance state of resistive random-access memory of Example 1, the high-low resistance state of Comparative Example 2 was relatively unstable, and the difference in resistance values between the high and low resistance states of Comparative Example 2 was smaller than that of Example 1.

Therefore, according to the test result of the above Example 1 and Comparative Examples 1-2, comparing to the conventional resistive random-access memory, the resistive random-access memory provided by the present invention can maintain the current-voltage stability and the high-low resistance stability, as well as maintain the significant difference in resistance values between the high and low resistance states by having the filament path control layer. Furthermore, according to the test result of the above Example 2, the resistive random-access memory of the present invention is quite suitable for producing a flexible memory array.

It should be understood that these examples are merely illustrative of the present invention and the scope of the invention should not be construed to be defined thereby, and the scope of the present invention will be limited only by the appended claims.

What is claimed is:

1. A resistive random-access memory, comprising:
a bottom electrode;
a resistive switch layer disposed on the bottom electrode, comprising a first switch layer, a second switch layer, and a filament path control layer, wherein the first switch layer is interposed between the bottom electrode and the filament path control layer, and the filament path control layer is interposed between the first switch layer and the second switch layer; and
a top electrode disposed on the second switch layer, wherein one or more micro-pores locates in or on the filament path control layer.

2. The resistive random-access memory of claim 1, wherein the filament path control layer is composed of single or multiple graphene layers.

3. The resistive random-access memory of claim 1, wherein the filament path control layer has a thickness of 1 nm to 10 nm.

4. The resistive random-access memory of claim 1, wherein the micro-pores have a pore size of 0.1 μm to 10 μm.

5. The resistive random-access memory of claim 1, wherein the first switch layer, and the second switch layer are independently silicon dioxide, titanium dioxide, vanadium dioxide, chromium(III) oxide, manganese oxide, iron oxide, cobalt oxide, nickel oxide, copper oxide, strontium titanate, strontium zirconate, lead titanate, praseodymium calcium manganite, aluminum oxide, hafnium oxide, gadolinium sesquioxide, or the combination thereof.

6. The resistive random-access memory of claim 5, wherein the first switch layer and the second switch layer are silicon dioxide.

7. The resistive random-access memory of claim 1, wherein the first switch layer has a thickness of 25 nm to 100 nm, and the second switch layer has a thickness of 25 nm to 100 nm.

8. The resistive random-access memory of claim 1, wherein the contact area between the bottom electrode and the first switch layer is larger than the contact area between the top electrode and the second switch layer; or the contact area between the bottom electrode and the first switch layer is equal to the contact area between the top electrode and the second switch layer.

9. A memory array, comprising a substrate, and a plurality of the resistive random access memories of claim 1, wherein the resistive random access memories are disposed on the substrate.

10. The memory array of claim 9, wherein the substrate is a plastic substrate, an aluminum substrate, or a combination thereof.
